(19) United States
(12) Patent Application Publication
(10) Pub. No.: US 2014/0119981 A1
(43) Pub. Date: May 1, 2014

(54) CONSTRUCTING BISMUTH ANTIMONY THIN FILMS WITH ANISOTROPIC SINGLE-DIRAC CONES

(71) Applicant: MASSACHUSETTS INSTITUTE OF TECHNOLOGY, Cambridge, MA (US)

(72) Inventors: Shuang Tang, Cambridge, MA (US); Mildred S. Dresselhaus, Arlington, MA (US)

(73) Assignee: Massachusetts Institute of Technology, Cambridge, MA (US)

(21) Appl. No.: 13/660,084

(22) Filed: Oct. 25, 2012

(51) Int. Cl. C30B 29/52; C22C 12/00

(52) U.S. Cl. CPC C30B 29/52; C22C 12/00; Y10S 977/755; Y10S 977/81; Y10S 977/84; B82Y 99/00
USPC 420/577; 117/4; 117/11; 117/84; 977/755; 977/810; 977/840

(57) ABSTRACT

A Bi₁₋ₓSbₓ thin film is provided that includes a Dirac-cone with different degrees of anisotropy in their electronic band structure by controlling the stoichiometry, film thickness, and growth orientation of the thin film, so as to result in a consistent inverse-effective mass tensor including non-parabolic or linear dispersion relations.

### GOVERNMENT SPONSORSHIP

This invention was made with government support under Grant Nos. DE-SC0001299 and DE-FG02-09ER46577 awarded by the Department of Energy and under Contract No. FA9550-10-1-0533 awarded by the U.S. Air Force. The government has certain rights in the invention.

### BACKGROUND OF THE INVENTION

The invention is related to bismuth antimony thin films, and in particular to bismuth antimony thin films that have anisotropic single-Dirac cones in the electronic band structure.

Materials with two-dimensional (2D) Dirac cones in their electronic band structures have recently attracted considerable attention. Many studies have been carried out on both massless and massive 2D Dirac fermions, including studies of the half-integer quantum Hall effect, the anomalous absence of back scattering, the Klein paradox effect, high temperature superconductivity, and unusual microwave response effects. The ultrahigh carrier mobility of the Dirac fermions in graphene offers new opportunities for a variety of electronics applications. Recently, 2D Dirac cones observed in topological insulators have identified this class of materials as candidates for quantum computation, spintronics, novel superconductors, and promising thermoelectrics materials.

Materials with 2D single-Dirac-cones, especially 2D anisotropic single-Dirac-cones, are of special interest. Simulations with ultracold atoms trapped on optical lattices have been used to study general 2D single-Dirac-cones. It is believed that graphene superlattice materials, which are described by anisotropic 2D single-Dirac-cones, could potentially be developed for use in nano-electronic-circuits without cutting processes, and in table-top experiments that simulate high-energy relativistic particles propagating in anisotropic space.

Bismuth antimony alloys have many interesting properties. Firstly, it has been shown that the band structure of three-dimensional (3D) bulk bismuth antimony can be varied as a function of antimony composition, temperature, pressure and strain, and the Fermi level can be adjusted to change the electronic properties. Secondly, not only have bulk state Dirac points been studied in bulk bismuth antimony alloys, but also the first observation of a surface state 2D single-Dirac-cone for a topological insulator was made in bulk Bi_{0.9}Sb_{0.1}. Some 2D experiments on bismuth antimony thin films grown normal to the trigonal direction have already been carried out. However, possible Dirac-cone materials of 2D bismuth antimony thin films have not yet been studied. Experiments have shown that the electronic band structure of bulk bismuth antimony does not change much over temperatures below the liquid nitrogen boiling point (77 K).

### SUMMARY OF THE INVENTION

According to one aspect of the invention, there is provided a Bi₁₋ₓSbₓ thin film. The Bi₁₋ₓSbₓ thin film includes a Dirac-cone with different degrees of anisotropy in their electronic band structure by controlling the stoichiometry, film thickness, and growth orientation of the thin film, so as to result in a consistent inverse-effective mass tensor including non-parabolic or linear dispersion relations.

According to another aspect of the invention, there is provided a method of forming a thin film having a Dirac-cone. The method includes forming a plurality of electronic band structures as a function of varying temperature, pressure, stoichiometry, film thickness, and growth orientation. Also, the method includes positioning the electronic band structures to result in a consistent inverse-effective mass tensor including a non-parabolic or linear dispersion relation.

### BRIEF DESCRIPTION OF THE DRAWINGS

FIG. 1 is a schematic diagram illustrating the 3-fold degenerate L points L⁽¹⁾, L⁽²⁾, L⁽³⁾ and the T point in the first Brillouin zone of bulk Bi₁₋ₓSbₓ;

FIGS. 2A-2E are schematic diagrams and graphs illustrating a L⁽¹⁾-point single-Dirac-cone being formed;

FIGS. 3A-3F are graphs and schematic diagrams illustrating different anisotropic single-Dirac-cones in different Bi_{0.96}Sb_{0.04} thin films; and

FIGS. 4A-4C are graphs and schematic diagrams illustrating the degree of anisotropy of the L⁽¹⁾-point single-Dirac-cone vs. film growth orientation within the trigonal-bisectrix crystalline plane.

### DETAILED DESCRIPTION OF THE INVENTION

The invention involves the electronic band structures of Bi₁₋ₓSbₓ thin films that can be varied as a function of stoichiometry, film thickness, and growth orientation. Different anisotropic single-Dirac-cones can be constructed in a Bi₁₋ₓSbₓ thin film for different applications or research purposes. For predicting anisotropic single-Dirac-cones, an iterative-two-dimensional two-band model is implemented to calculate a consistent inverse-effective-mass tensor and band gap at the L point in the first Brillouin zone, which can be used in a general two-dimensional system that has a non-parabolic dispersion relation as in the Bi₁₋ₓSbₓ thin film system (0≦x≦0.3).

The invention focuses on the cryogenic temperature range. The invention has provided a concept for Bi₁₋ₓSbₓ thin films that have anisotropic single-Dirac-cones with different degrees of anisotropy in the electronic band structure at the L-point in the first Brillouin zone can be constructed by controlling the parameters: film thickness, growth orientation and stoichiometry. The electronic properties of the 2D L-point single Dirac-cones in Bi₁₋ₓSbₓ thin films have been studied, such as their anisotropy and linearity, and change as a function of film thickness, growth orientation and stoichiometry. An iterative-two-dimensional two-band model is implemented in the study, which could be used as a general model to study low-dimensional materials systems with non-parabolic dispersion relations or Dirac cones in the electronic band structures.

The band-gap and band-overlap of bulk Bi can be changed by adding Sb to form Bi₁₋ₓSbₓ alloys. 3D Dirac points may form under proper conditions at the three L points, when the valence band and the conduction band exhibit a band-crossing. At each L point, E(k) becomes linear in the limit of band-crossing (E_{g}→0), since

$$E ( k ) = \pm {( {( v \cdot p )}^{2} + {E}_{g}^{2} )}^{\frac{1}{2}} ,$$

where v is the carrier velocity, p is the carrier momentum, and E_{g} is the L-point direct band-gap. Historically, the 3D two-band model has been successful in describing the non-parabolic dispersion relation E(k) in 3D bulk Bi materials by

$$p \cdot a \cdot p = E ( k ) ( 1 + \frac{E ( k )}{{E}_{g}} ) , \qquad ( 1 )$$

where α is the inverse-effective-mass-tensor, and one can assume here that α is the same for both the conduction band and the valence band within the context of a two-band model and strong interband coupling. Generally, the relation between α and E_{g} around an L point is described as

$$a = \frac{2}{{ℏ}^{2}} \frac{{\partial }^{2} E ( k )}{\partial {( k - {k}_{L} )}^{2}} = \frac{1}{{m}_{0}} \cdot I \pm \frac{1}{{m}_{0}^{2}} \frac{2}{{E}_{g}} \cdot {p}^{2} , \qquad ( 2 )$$

under the k·p approximation, where I is the identity matrix and m₀ is the free electron mass. It is assumed that a two-band model also applies to Bi₁₋ₓSbₓ alloys, where the influence on a of adding Sb atoms up to a Sb concentration of x=0.3 to bulk Bi is then

$$a ( {Bi}_{1 - x} {Sb}_{x} ) = \frac{{E}_{g} ( Bi )}{{E}_{g} ( {Bi}_{1 - x} {Sb}_{x} )} \cdot ( a ( Bi ) - \frac{1}{{m}_{0}} \cdot I ) + \frac{1}{{m}_{0}} \cdot I . \qquad ( 3 )$$

An iterative-two-dimensional-two-band model is developed for Bi₁₋ₓSbₓ thin films, where both α^{film} and E_{g}^{film} of a Bi₁₋ₓSbₓ thin film differ from α^{bulk} and E_{g}^{bulk} in the 3D bulk case, and they are both unknown at the start. The conduction band and the valence band at an L point are firstly separated by E_{g}^{[0]}=E_{g}^{bulk} (Bi) and the inverse-effective-mass-tensor is α^{[0]}=α^{bulk} (Bi). In a Bi₁₋ₓSbₓ thin film, the L-point gap can be influenced by both the added Sb atoms and the quantum confinement effect, so that the L-point gap to the lowest order approximation becomes

$${E}_{g}^{[ 1 ]} = {E}_{g}^{bulk} ( {Bi}_{1 - x} {Sb}_{x} ) + 2 \cdot \frac{{h}^{2} {α}_{33}^{[ 0 ]}}{8 \cdot {l}_{z}^{2}} . \qquad ( 4 )$$

The change in the L-point gap can lead to a change of the L-point inverse-effective-mass-tensor according to

$${a}^{[ n ]} = \frac{{E}_{g}^{[ n - 1 ]}}{{E}_{g}^{[ n ]}} \cdot {a}^{[ n - 1 ]} + \frac{1}{{m}_{0}} \cdot ( 1 - \frac{{E}_{g}^{[ n - 1 ]}}{{E}_{g}^{[ n ]}} ) \cdot I , \qquad ( 5 )$$

where n denotes the step number in the iteration. Eq. (5) is a general equation for iterations, which is just a consequence of Eq. (3). Thereafter, the L-point band-gap can be updated with the new inverse-effective-mass-tensor by

$${E}_{g}^{[ n + 1 ]} = {E}_{g}^{[ n ]} + 2 \cdot \frac{{h}^{2} {α}_{33}^{[ n ]}}{8 \cdot {l}_{z}^{2}} . \qquad ( 6 )$$

The iterative procedure is repeated until α^{[n]} and E_{g}^{[n]} become self-consistent, and then one gets an accurate solutions for α^{[n]}=α^{film} (Bi₁₋ₓSbₓ) and E_{g}^{[n]}=E_{g}^{film} (Bi₁₋ₓSbₓ) for the Bi₁₋ₓSbₓ thin film. The Hamiltonian for Bi and Bi₁₋ₓSbₓ based on k·p theory in this model is equivalent to a Dirac Hamiltonian with a scaled canonical conjugate momentum. Thus, Eqs. (5) and (6) are also good approximations to describe the Dirac cones. The band parameters used in the present calculations are values that were measured by cyclotron resonance experiments.

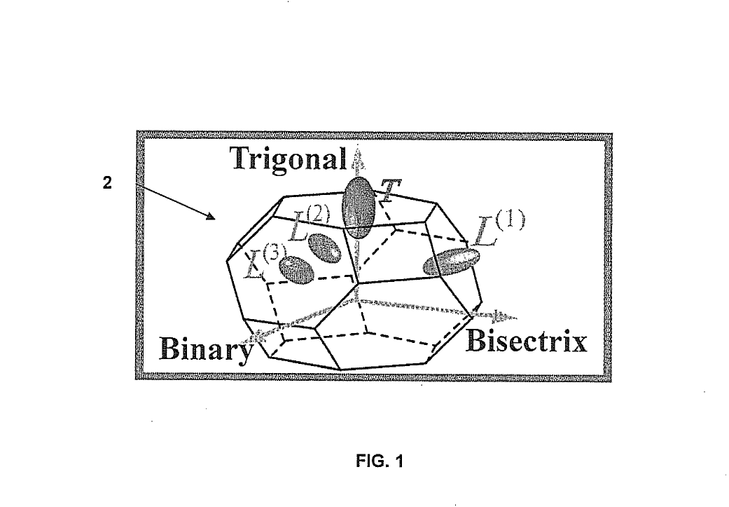

There are three symmetrical L points L⁽¹⁾, L⁽²⁾, L⁽³⁾ in the first 3D Brillouin zone of Bi₁₋ₓSbₓ as shown in FIG. 1. In order to get a single-Dirac-cone, one needs to grow the Bi₁₋ₓSbₓ thin film normal to a low symmetry direction so that one can have a single L-point that differs from the other two by breaking the 3-fold symmetry occurring in 3D. Moreover, two quantities in Eq. (4) need to be minimized, namely the bulk-band-gap term E_{g}^{bulk} (Bi₁₋ₓSbₓ) and the quantum-confinement-induced term h²α₃₃^{[0]}/4·l_{z}² for this special single L-point T. Thus, growing a film normal to the bisectrix direction is a good way to break the 3-fold symmetry and the α₃₃ inverse mass component is near its minimum for this film direction, which is discussed below.

Minimizing the value of the bulk term E_{g}^{bulk} (Bi₁₋ₓSbₓ) by varying the temperature T, pressure P and Sb composition x has been known, especially for the case of x=0.04, where E_{g}^{bulk} (Bi₁₋ₓSbₓ) decreases to 0 at cryogenic temperatures and under atmospheric pressure. Thin films with the composition Bi_{0.96}Sb_{0.04} have already been synthesized in experiments for films grown normal to the trigonal direction. The model that is valid for all values of Sb composition x (≦0.3). However, for the convenience of experimentalists to use the theoretical predictions, simple examples are provided of single-Dirac-cones that can be found in Bi_{0.96}Sb_{0.04}. More generally, Bi₁₋ₓSbₓ thin films of other Sb compositions x can be modeled in the similar way.

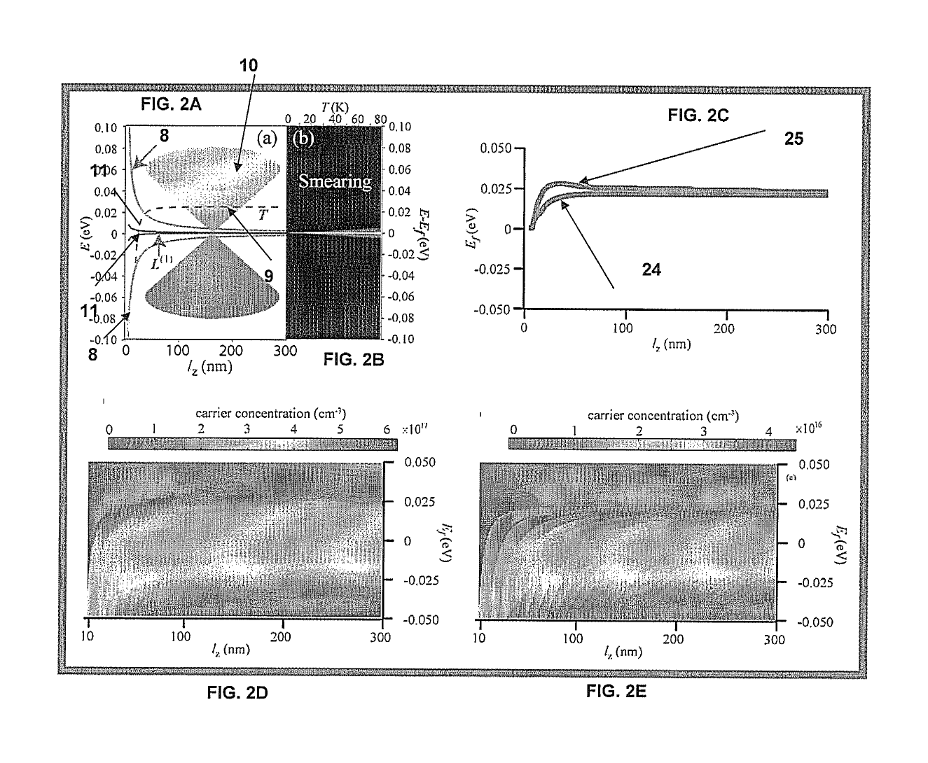

Based on the inventive model, a single 2D Dirac cone can be constructed in a Bi_{0.96}Sb_{0.04} thin film normal to the bisectrix axis. For this thin film the 3-fold symmetry of the L points in reciprocal space is broken. According to our calculations, the L⁽¹⁾-point band gap E_{g}^{L}^{⁽¹⁾} will not exceed: 1 meV until the film is thinner than 80 nm. However, the L⁽²⁾- and L⁽³⁾-point band gaps E_{g}⁽²⁾ (E_{g}^{L}^{⁽²⁾}=E_{g}^{L}^{⁽³⁾}) will open up and increase significantly when the film thickness decreases. When l_{z}=300 nm, E_{g}^{L}^{⁽²⁾} and E_{g}^{L}^{⁽³⁾} are already larger than 7 meV, while E_{g}^{L}^{⁽¹⁾} is still smaller than 0.1 meV. This means that a single-Dirac-cone 10 is formed at the L⁽¹⁾ point, as shown in FIG. 2A. FIG. 2A shows the band structure of a Bi_{0.96}Sb_{0.04} thin film grown normal to the bisectrix axis and how the band structure changes over different film thicknesses. The Curves 8 show the lowest conduction band (upper one) and the highest valence band (lower one) at the L⁽²⁾ and L⁽³⁾ points. The Curves 11 are for the L⁽¹⁾ point. The dashed Curve 9 is the highest valence band at the T point. The L⁽¹⁾-point band gap remains less than the order of: 1 meV until the film thickness l_{z} is very small. The L⁽²⁾ and L⁽³⁾ points have the same band gap, which is largely opened up. Thus, an anisotropic single-Dirac-cone is formed at the PP point when the film thickness l_{z} is large enough to retain the L⁽¹⁾-point mini-gap essentially zero, i.e. less than: 1 meV. In FIG. 2A, the curves 8 show the lowest conduction band (upper one) and the highest valence band (lower one) at the L⁽²⁾ and L⁽³⁾ points. The curves 11 are for the L⁽¹⁾ point. The curve 9 is the highest valence band at the T point. The L⁽¹⁾-point band gap remains less than about: 1 meV until the film thickness 1, is very small. The L⁽²⁾ and L⁽³⁾ points (shown by the curve 8) have the same band gap as one another, which is largely opened up.

Up to now, the band structure and the dispersion relations at the L points have been discussed. Another important aspect is the Fermi level E_{f}, which determines the carrier density and transport properties. The Fermi level for a Bi₁₋ₓSbₓ thin film changes with film thickness, temperature, external gate voltage and impurity doping. For further discussion of how the Fermi level influences the physical properties of the single-Dirac-cone, one can assume that the Fermi level for a specific Bi₁₋ₓSbₓ thin film can be varied freely within the range of 0 to 25 meV without destroying the single-Dirac-cone. How the carrier concentration changes with film thickness and temperature will be discussed later.

The carriers that contribute to transport are the ones that are within the smearing range of the Fermi-Dirac distribution

$$( - \frac{\partial {f}_{0}}{\partial E} ) ,$$

where f₀=(1+exp[(E−E_{f})/k_{B}·T])⁻¹. The quantity of

$$( - \frac{\partial {f}_{0}}{\partial E} )$$

is very sharp over E at cryogenic temperatures as shown in FIG. 2B, and has a width in the order of: k_{B}·T. FIG. 2B shows the thermal smearing

$$( - \frac{\partial {f}_{0}}{\partial E} )$$

of the Fermi-Dirac distribution as a function of cryogenic temperature. For comparison to FIG. 2A, the Fermi level in FIG. 2B is aligned with E=0 to indicate the absence of carriers due to dopants. In this case, the Fermi level is at the apex of the L⁽¹⁾-point single-Dirac-cone. Then the Dirac fermions which contribute to transport can only come from this L⁽¹⁾-point single-Dirac-cone, and not from the L⁽²⁾ or L⁽³⁾ points, at cryogenic temperatures. Cases where the Fermi level E_{f} is at other positions can be discussed in the similar way. Only carriers within smearing will get excited and contribute to the transport phenomena.

FIG. 2C shows the Fermi level for intrinsic Bi_{0.96}Sb_{0.04} films without doping or gate voltage. If no doping is added and no gate voltage is applied, the l_{z} dependence of the intrinsic Fermi levels is shown at 77 K (Curve 25) and at 4.2 K (Curve 24). The carrier concentration of Bi_{0.96}Sb_{0.04} vs. film thickness l_{z} and Fermi level are shown at 77 K, which is shown in FIG. 2D and at 4.2 K, which is shown in FIG. 2E. At cryogenic temperatures, the intrinsic Fermi level starts to drop with film thickness when the film is thinner than: 40 nm, which reveals the semimetal-semiconductor transition, where the T-point valence band falls below the L⁽¹⁾-point conduction band, consistent with the prediction of FIG. 2A. How the carrier concentration for a Bi_{0.96}Sb_{0.04} film changes as a function of film thickness and Fermi level is calculated next. FIGS. 2D and 2E, respectively, show the total carrier concentrations for a Bi_{0.96}Sb_{0.04} film at the liquid nitrogen boiling point (77 K) and the liquid helium boiling point (4.2 K). The overall carrier concentration is very low (: 10¹⁷ cm⁻³) at 77 K and much lower (: 10¹⁶ cm⁻³) at 4.2 K.

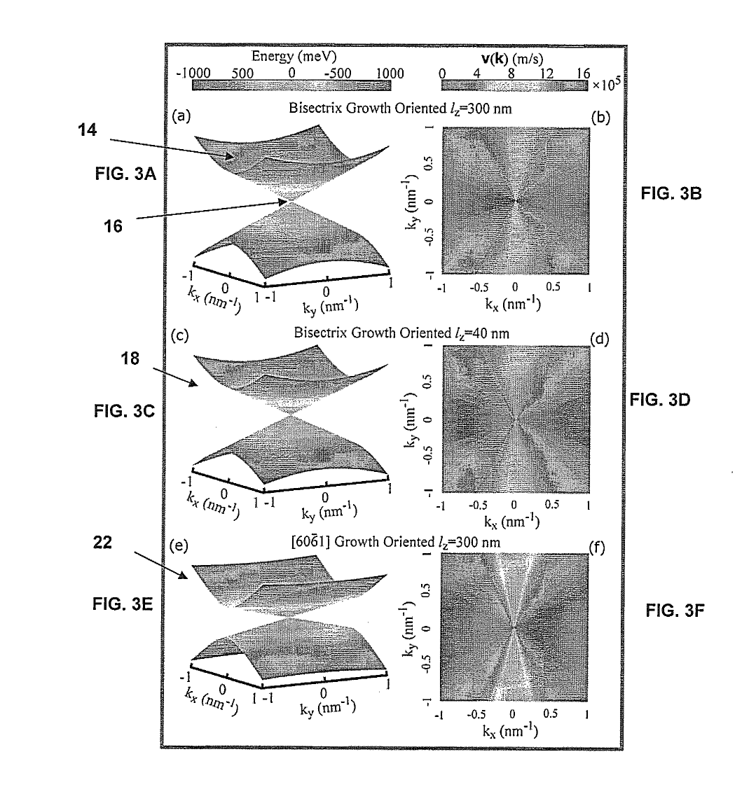

There are two kinds of Dirac fermions associated with a Dirac cone that researchers are interested in, the massless Dirac fermions and the massive Dirac fermions. In experiments, a Dirac cone is usually not perfect. A mini-gap often exists which induces a mini-mass at the apex of the Dirac cone. Such an effect also occurs in single layer graphene. Therefore, practically, there are two main features that characterize the quality of a Dirac cone, the mini-mass for the “massless” Dirac fermions occurring at the apex, and the fermion velocity v(k) as a function of k for the massive Dirac fermions. Because the fermions are linearly dispersed near a Dirac cone, v(k) should only be a function of the direction of k. The anisotropy of the Dirac cone can be characterized by the ratio between the maximum and the minimum values of v(k). FIGS. 3A-3F have shown different anisotropic single-Dirac-cones in different Bi_{0.96}Sb_{0.04} thin films: FIGS. 3A and 3B describe a sharp-apex L⁽¹⁾-point anisotropic single-Dirac-cone in a 300 nm thick Bi_{0.96}Sb_{0.04} film grown normal to the bisectrix axis. For convenience, the origin of momentum k is chosen to be at the L⁽¹⁾ point. FIGS. 3C and 3D describe an L⁽¹⁾-point anisotropic single-Dirac-cone where the T-point carrier-pocket is totally below the L⁽¹⁾-point Dirac cone, in a 40 nm thick Bi_{0.96}Sb_{0.04} film grown normal to the bisectrix axis. FIGS. 3E and 3F describe a highly anisotropic single-Dirac-cone in a 300 nm thick Bi_{0.96}Sb_{0.04} film grown normal to the [60 6̅1] crystalline direction. FIGS. 3A, 3C and 3E show the dispersion relations of these single-Dirac-cones. FIGS. 3B, 3D and 3F show the group velocities v of Dirac fermions over different momenta k. FIGS. 3C and 3D are not significantly different from FIGS. 3A and 3B, but FIGS. 3E and 3F are obviously more anisotropic than FIGS. 3A and 3B and FIGS. 3C and 3D.

The L⁽¹⁾-point anisotropic single-Dirac-cone 14 in a 300 nm thick Bi₁₋ₓSbₓ thin film grown normal to the bisectrix axis has a linear E(k) behavior with a very sharp apex 16 as shown in FIG. 3A. In this film, kₓ and k_{y} represent the wave vectors along the trigonal axis and the binary axis, respectively. E_{g}^{L}^{⁽¹⁾} for this Dirac cone is smaller than 0.1 meV, and the effective mass at the apex of the Dirac cone is: 10⁻⁵ m₀, which can be considered as essentially gapless and massless. Also, the v(k) relation of the Dirac fermions for different values of momentum are calculated, as shown in FIG. 3B. For the anisotropy of this single-Dirac-cone, it can be seen that the maximum and the minimum of v(k) are 1.6·c_{light}/300 (along kₓ) and 1.1·c_{light}/300, (along k_{y}), respectively, which differs by a factor of: 1.5, where c_{light} is the speed of light.

The contribution of the L⁽¹⁾-point single-Dirac-cone fermions to the transport properties is much greater than that contributed by the parabolically dispersed fermions at the T point. In bulk Bi and Bi₁₋ₓSbₓ at cryogenic temperatures, it has been shown both theoretically and experimentally that the transport properties are dominated by the L-point carriers, which have ultra-high electron and hole mobilities, because of the ultra-large carrier group velocities of the L⁽¹⁾ point carriers. This is not difficult to understand and can be explained in a very simple manner. For example, the electronic conductivity of the carriers for a specific carrier pocket is

$${σ}_{ij} = {e}^{2} {D}_{{E}_{f}} \cdot {v}_{i} \cdot {\sum }_{l} {( {τ}_{{E}_{f}} )}_{jl} \cdot {v}_{l} , \qquad ( 7 )$$

where τ_{E}_{_{f}} and D_{E}_{_{f}} are, respectively, the anisotropic relaxation time tensor and the density of states for carriers of this specific carrier pocket at the Fermi level E_{f}, and i, j and l denote components of the various vector and tensor quantities. One can take the principal axis along kₓ as an example, i.e. i=j=x and σₓₓ=e²D_{E}_{_{f}}(τ_{E}_{_{f}})ₓₓ·vₓ². In Bi and Bi₁₋ₓSbₓ, the relaxation time (τ_{E}_{_{f}})ₓₓ=λₓₓvₓ⁻¹, where λₓₓ is the mean free path and λₓₓ∝D_{E}_{_{f}}⁻¹. Thus, one can have σₓₓ∝vₓ(E_{f}), where vₓ(E_{f}) is the carrier group velocity component along the kₓ direction for this specific carrier pocket at the Fermi level E_{f}. For the L-point Dirac fermions, vₓr^{[Dirac]}(E_{f}): 10⁻²·c_{light}, while for the T-point parabolically dispersive fermions, vₓ^{[T]}(E_{f}): 10³ m/s, thereby explaining why σₓₓ^{[Dirac]}?σₓₓ^{[T]}. The difference of the electrical conductivity between the thin film Bi₁₋ₓSbₓ and the bulk Bi₁₋ₓSbₓ can be explained by the classical confinement effect and the quantum confinement effect as discussed hereinafter. The quantum confinement effect is accounted for by the band structure itself. The classical confinement effect comes from the film boundary scattering mechanism, which can be described by the empirical relation

$$\frac{{σ}_{{l}_{z}}}{{σ}_{bulk}} = {C}_{1} \cdot {l}_{z} \cdot ( {C}_{2} - ln {l}_{z} ) ,$$

where σₗ_{_{z}} is the electrical conductivity for the thin film with thickness l_{z}, while σ_{bulk} is the bulk electrical conductivity, and C₁ and C₂ are empirical constants that can be measured by experiments. Based on the above, one knows that the main factor that determines the electrical conductivity in a Bi₁₋ₓSbₓ thin film is also the carrier group velocity, and since the L⁽¹⁾-point Dirac fermions have much larger group velocities than the T-point parabolically dispersive fermions, it is believed that the electrical conductivity is dominated by the L⁽¹⁾-point Dirac cone.

Moreover, the T-point parabolically dispersed carrier pocket can also be moved further down in energy below the L⁽¹⁾-point single-Dirac-cone, in a 2D Bi_{0.96}Sb_{0.04} thin film, which is not achieved in bulk Bi_{0.96}Sb_{0.04}. When the film thickness decreases, the top point of the T-point valence band decreases in energy much faster than the L⁽¹⁾-point valence band as shown in FIG. 2A. When the film thickness is less than 40 nm, the T-point valence band is totally below the bottom of the L⁽¹⁾-point conduction band, indicating a semimetal-semiconductor transition. The effective mass at the apex of this single-Dirac-cone is: 10⁻⁴ m₀, which is still essentially massless. The corresponding Dirac cone 18 is plotted in FIG. 3C, as well as the velocity vs. momentum relation v(k) for the massive Dirac fermions which is shown in FIG. 3D. The linearity and the anisotropy of the Dirac cone is not notably influenced by film thickness for a film of l_{z}=40 nm in comparison to the one with l_{z}=300, as can be seen by comparing FIGS. 3C and 3D to FIGS. 3A and 3B, respectively.

In some applications, e.g. in nano-electronic-circuit design, a higher anisotropy of the Dirac cone could be required. For a Bi_{0.96}Sb_{0.04} thin film, the L⁽¹⁾-point E(k) has a smaller mini-mass at the apex but a lower anisotropy if the film is grown normal to the bisectrix axis, while the L⁽¹⁾-point E(k) has a larger mini-mass at the apex but a higher anisotropy if the film is grown normal to the trigonal axis. This gives us an idea that a film grown normal to a crystalline direction between the trigonal axis and the bisectrix axis, would have both a small mini-mass and a high anisotropy. As an example, FIGS. 3E and 3F illustrate a film grown normal to a low-symmetrical crystalline direction \hat{n}, where \hat{n} is in the trigonal-bisectrix plane, making an angle of 14° to the bisectrix axis and 76° to the trigonal axis. In the hexagonal notation system for the rhombohedral Bi₁₋ₓSbₓ, the trigonal axis is [0001] and the bisectrix axis is [10 1̅0]. Thus, \hat{n} can be denoted as [60 6̅1]. Here \hat{n} is just a randomly chosen crystalline direction within the trigonal-bisectrix plane to be an example, and other crystalline directions can be discussed in the similar way. FIGS. 3E and 3F illustrate a 300 nm thick film grown normal to \hat{n}, where k_{y} is still along the binary axis, while kₓ is in the direction perpendicular to both the binary axis and \hat{n}. Then E_{g}^{L}^{⁽¹⁾} for this Dirac cone 22, as shown in FIG. 3E, is smaller than 0.46 meV, and the mini-mass at the apex of the Dirac cone is still negligible (: 10⁻⁴ m₀). The anisotropy for this single-Dirac-cone, as shown in FIG. 3E, is much higher. The maximum and minimum values of v(k) for the massive Dirac fermions are 1.65·c_{light}/300 and 0.55·c_{light}/300, respectively, which differ by a factor of: 3, as shown in FIG. 3F.

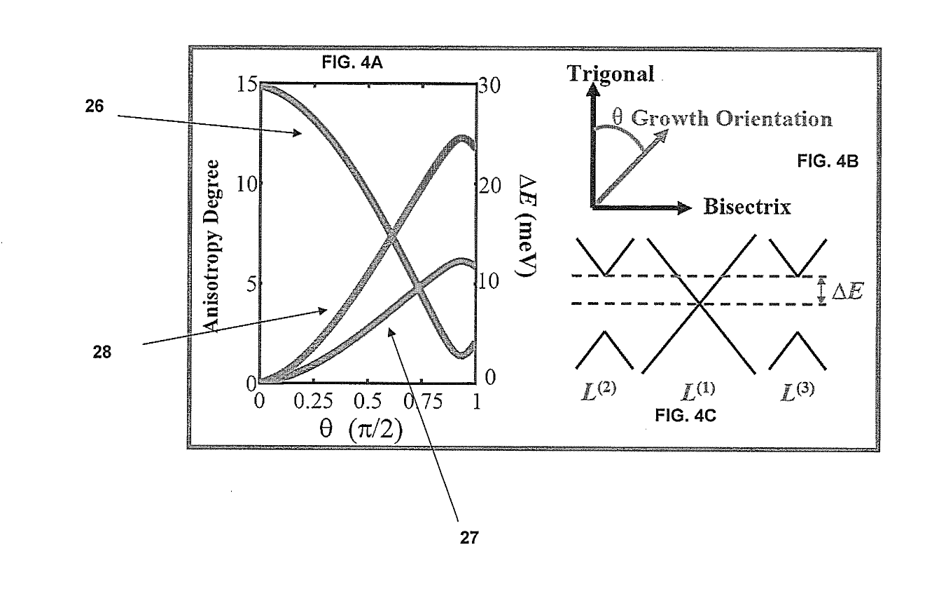

Generally, the anisotropy of the L⁽¹⁾-point single-Dirac-cone can be controlled by the film growth orientation. For a growth orientation between the trigonal-bisectrix plane, the degree of anisotropy of the L⁽¹⁾-point Dirac cone is calculated and plotted in FIG. 4A, where the degree of anisotropy is defined as the ratio of the maximum to the minimum values of the v(k) for the massive L⁽¹⁾-point Dirac fermions. FIGS. 4A-4C show anisotropy degree of the L⁽¹⁾-point single-Dirac-cone vs. film growth orientation within the trigonal-bisectrix crystalline plane (Curve 26). The differences in energy between the L⁽¹⁾-point conduction band edge and the L⁽²⁾ (L⁽³⁾)-point conduction band edge ΔE, for 100 nm thick films (Curve 27) and 50 nm (Curve 28) thick films as a function of film growth orientation are also shown. θ is the angle between the growth orientation and the trigonal axis in the trigonal-bisectrix plane. θ=0 stands for the trigonal growth, and θ=π/2 stands for the bisectrix growth. When the film growth orientation is in the trigonal-bisectrix plane, the L⁽²⁾-point and the L⁽³⁾-point are in reflection symmetry, and hence degenerate in energy. The Curve 27 and the Curve 28 shows how the L⁽¹⁾ point become different from the L⁽²⁾ and L⁽³⁾ points, when the film growth orientation changes from the trigonal direction to the bisectrix direction within the trigonal-bisectrix plane. The degree of anisotropy of the L⁽¹⁾-point Dirac fermions can be varied within a wide range from ˜1 to ˜15 according to FIG. 4B by growing the film along different crystalline directions. On the other hand, the trigonal-bisectrix crystalline plane is the mirror plane for the reflection symmetry of the crystal lattice, so the L⁽²⁾ point and the L⁽³⁾ point are always in mirror symmetry with respect to each other, and hence the bottom of the L⁽²⁾-point and the L⁽³⁾-point conduction band edges are degenerate in energy. The difference in energy between the L⁽¹⁾-point conduction band edge and the L⁽²⁾-point (L⁽³⁾-point) conduction band edge as a function of film growth orientation is also plotted in FIG. 4C, as a guidance for experiments, which shows how the L⁽¹⁾ point becomes different from the L⁽²⁾- and L⁽³⁾-points in energy. The 100 nm thick films and the 50 nm thick films are illustrated in FIG. 4A as examples.

The technology needed for experimental implementations of the Bi₁₋ₓSbₓ thin films described above is foreseeable. Single Bi and Bi₁₋ₓSbₓ thin films grown normal to the trigonal axis, as well as polycrystal Bi thin films grown with preference to a low symmetry direction have been synthesized, and so have single crystal Bi and Bi₁₋ₓSbₓ nanowires grown along various crystalline directions. The cryogenic measurement of transport, optical and magnetical properties of bulk Bi and Bi₁₋ₓSbₓ have also been developed to a very high level of sophistication over decades of efforts. For single crystalline Bi₁₋ₓSbₓ thin film samples, an anisotropic single-Dirac-cone should be observed. For a mosaic single crystalline Bi₁₋ₓSbₓ thin film sample grown along a low-symmetry direction, but with disorder in the in-plane direction of grains, the in-plane anisotropy would be sacrificed depending on the degree of the disorder. When the in-plane disorder achieves a total randomness, an isotropic single-Dirac-cone should be observed, which might be interesting for research related to the phase factor of Dirac fermions.

The invention provides an iterative-two-dimensional-two-band model to describe a general 2D non-parabolic anisotropic dispersion relation. Based on this theory, Bi₁₋ₓSbₓ thin films can be constructed that have anisotropic single-Dirac-cones of different degrees of anisotropy in the Brillouin zone of electronic band structure. Some critical cases of L⁽¹⁾-point single-Dirac-cones are illustrated as examples. Novel physical phenomena associated with massless and massive Dirac fermions that have been previously reported in other materials systems could hopefully also be observed in Bi₁₋ₓSbₓ thin films. Because the Bi₁₋ₓSbₓ thin film system has special features as discussed above, one can also expect to observe new physical phenomena that have never been observed in other systems.

Although the present invention has been shown and described with respect to several preferred embodiments thereof, various changes, omissions and additions to the form and detail thereof, may be made therein, without departing from the spirit and scope of the invention.

What is claimed is:

1. A Bi₁₋ₓSbₓ thin film comprising a Dirac-cone with different degrees of anisotropy in electronic band structure by controlling the stoichiometry, film thickness, and growth orientation of the thin film, so as to result in a consistent inverse-effective mass tensor including non-parabolic or linear dispersion relations.

2. The Bi₁₋ₓSbₓ thin film of claim 1, wherein the growth orientation is along a bisectrix direction.

3. The Bi₁₋ₓSbₓ thin film of claim 1, wherein the growth orientation is along low symmetry direction.

4. The Bi₁₋ₓSbₓ thin film of claim 3 further comprising disorders in the in-plane directions of grains.

5. The Bi₁₋ₓSbₓ thin film of claim 4, wherein the in-plane disorders achieve total randomness and an isotropic single-Dirac-cone is observed.

6. The Bi₁₋ₓSbₓ thin film of claim 2 further comprising symmetrical L-points.

7. The Bi₁₋ₓSbₓ thin film of claim 6, wherein the symmetrical L-points differ from a special L-point that allows the Bi₁₋ₓSbₓ thin film to be grown along a bisectrix direction where symmetry is broken and the inverse mass component is near minimum.

8. A method of forming a thin film having a Dirac-cone comprising:
forming a plurality of electronic band structures as a function of varying temperature, pressure, stoichiometry, film thickness, and growth orientation; and
positioning the electronic band structures to result in a consistent inverse-effective mass tensor including a non-parabolic or linear dispersion relation.

9. The method of claim 8, wherein the growth orientation is along a bisectrix direction.

10. The method of claim 8, wherein the growth orientation is along a low-symmetry direction.

11. The method of claim 10 further comprising disorders in the in-plane directions of grains.

12. The method of claim 11, wherein the in-plane disorders achieve total randomness and an isotropic single-Dirac-cone is observed.

13. The method of claim 9 further comprising symmetrical L-points.

14. The method of claim 13, wherein symmetrical L-points differ, a special L-point that allows the Bi₁₋ₓSbₓ thin film to be grown along a bisectrix direction where symmetry is broken and the inverse mass component is near minimum.
